(19) United States
(12) Patent Application Publication
(10) Pub. No.: US 2025/0279296 A1
(43) Pub. Date: Sep. 4, 2025

(54) MASS TRANSFER ASSEMBLY, DISPLAY PANEL, AND DISPLAY DEVICE

(71) Applicant: HKC CORPORATION LIMITED, Shenzhen (CN)

(72) Inventors: Yang PU, Shenzhen (CN); Lidan YE, Shenzhen (CN)

(21) Appl. No.: 18/999,703

(22) Filed: Dec. 23, 2024

(30) Foreign Application Priority Data
Mar. 4, 2024 (CN) 202410239001.5

(51) Int. Cl. H01L 21/67; H01L 21/683; H10H 29/02; H10H 29/03; H10H 29/39

(52) U.S. Cl. CPC H01L 21/67144; H10H 29/02; H10H 29/03; H10H 29/39; H01L 21/6836

(57) ABSTRACT

A mass transfer assembly includes a temporary substrate and a transfer substrate. The temporary substrate is configured to adhere electrodes of each light-emitting element on a growth substrate, to separate each light-emitting element from the growth substrate, such that a light-emitting body of each light-emitting element is suspended. The transfer substrate is configured to adhere, through adhesion regions, a light-emitting body of each light-emitting element on the temporary substrate, to separate each light-emitting element from the temporary substrate, such that electrodes of each light-emitting element are suspended. One adhesion region adheres a light-emitting body of one light-emitting element. Positions of the adhesion regions on the transfer substrate are in one-to-one correspondence with positions of binding regions on a driving substrate. The transfer substrate is further configured to transfer each light-emitting element to the driving substrate, to bind electrodes of each light-emitting element to a corresponding binding region.

### CROSS-REFERENCE TO RELATED APPLICATION(S)

This application claims priority to Chinese Application Patent Serial No. 202410239001.5, filed Mar. 4, 2024, the entire disclosure of which is hereby incorporated by reference.

### TECHNICAL FIELD

This application relates to the field of display technology, and particularly to a mass transfer assembly, a display panel, and a display device having the display panel.

### BACKGROUND

Micro light-emitting diode (LED) display panels have broad application prospects in the display field because of their advantages of good stability, long life, excellent display effect, etc.

The micro LED display panel generally includes a driving substrate and millions of micro LED elements disposed on one side of the driving substrate. A distance between two adjacent micro LED elements on the driving substrate is mainly determined by a resolution and a size of the micro LED display panel. Micro LED elements are formed on the growth substrate. In order to improve a utilization rate of the growth substrate, a distance between two adjacent micro LED elements on the growth substrate should be as small as possible. However, if the distance between two adjacent micro LED elements on the growth substrate is smaller than the distance between two adjacent micro LED elements on the driving substrate, the micro LED elements on the growth substrate cannot be transferred to the driving substrate at one time, resulting in an increase in workload and cost of transferring of the micro LED elements.

Therefore, how to transfer the micro LED elements on the growth substrate to the driving substrate at one time to reduce workload and cost of transferring of the micro LED elements has become an urgent problem to be solved by those skilled in the art.

### SUMMARY

The disclosure provides a mass transfer assembly. The mass transfer assembly is used for transferring a plurality of light-emitting elements from a growth substrate to a driving substrate. Each of the plurality of light-emitting elements includes a light-emitting body initially connected with the growth substrate and two electrodes connected with the light-emitting body. The mass transfer assembly includes a temporary substrate and a transfer substrate. The temporary substrate is configured to adhere two electrodes of each of a plurality of light-emitting elements on the growth substrate, to separate the plurality of light-emitting elements from the growth substrate, such that a light-emitting body of each of the plurality of light-emitting elements is suspended. The transfer substrate has a plurality of adhesion regions. The transfer substrate is configured to adhere, through the adhesion regions, a light-emitting body of each of a plurality of light-emitting elements on the temporary substrate, to separate the plurality of light-emitting elements from the temporary substrate, such that two electrodes of each of the plurality of light-emitting elements are suspended. One adhesion region adheres a light-emitting body of one light-emitting element. Positions of the plurality of adhesion regions on the transfer substrate are in one-to-one correspondence with positions of a plurality of binding regions on the driving substrate. The transfer substrate is further configured to transfer a plurality of light-emitting elements on the transfer substrate to one side of the driving substrate, to bind two electrodes of each of the plurality of light-emitting elements to a corresponding binding region of the driving substrate.

The disclosure further provides a display panel. The display panel includes a driving substrate and a plurality of light-emitting elements disposed on one side of the driving substrate. The plurality of light-emitting elements are transferred by a mass transfer assembly from a growth substrate to the driving substrate. Each of the plurality of light-emitting elements includes a light-emitting body initially connected with the growth substrate and two electrodes connected with the light-emitting body. The mass transfer assembly includes a temporary substrate and a transfer substrate. The temporary substrate is configured to adhere two electrodes of each of a plurality of light-emitting elements on the growth substrate, to separate the plurality of light-emitting elements from the growth substrate, such that a light-emitting body of each of the plurality of light-emitting elements is suspended. The transfer substrate has a plurality of adhesion regions. The transfer substrate is configured to adhere, through the adhesion regions, a light-emitting body of each of a plurality of light-emitting elements on the temporary substrate, to separate the plurality of light-emitting elements from the temporary substrate, such that two electrodes of each of the plurality of light-emitting elements are suspended. One adhesion region adheres a light-emitting body of one light-emitting element. Positions of the plurality of adhesion regions on the transfer substrate are in one-to-one correspondence with positions of a plurality of binding regions on the driving substrate. The transfer substrate is further configured to transfer a plurality of light-emitting elements on the transfer substrate to the side of the driving substrate, to bind two electrodes of each of the plurality of light-emitting elements to a corresponding binding region of the driving substrate.

The disclosure further provides a display device. The display device includes a housing and a display panel. The display panel is received in the housing. A light-emitting side of the display panel is exposed from the housing. The display panel includes a driving substrate and a plurality of light-emitting elements disposed on one side of the driving substrate. The plurality of light-emitting elements are transferred by a mass transfer assembly from a growth substrate to the driving substrate. Each of the plurality of light-emitting elements includes a light-emitting body initially connected with the growth substrate and two electrodes connected with the light-emitting body. The mass transfer assembly includes a temporary substrate and a transfer substrate. The temporary substrate is configured to adhere two electrodes of each of a plurality of light-emitting elements on the growth substrate, to separate the plurality of light-emitting elements from the growth substrate, such that a light-emitting body of each of the plurality of light-emitting elements is suspended. The transfer substrate has a plurality of adhesion regions. The transfer substrate is configured to adhere, through the adhesion regions, a light-emitting body of each of a plurality of light-emitting elements on the temporary substrate, to separate the plurality of light-emitting elements from the temporary substrate, such that two electrodes of each of the plurality of light-emitting elements are suspended. One adhesion region adheres a light-emitting body of one light-emitting element. Positions of the plurality of adhesion regions on the transfer substrate are in one-to-one correspondence with positions of a plurality of binding regions on the driving substrate. The transfer substrate is further configured to transfer a plurality of light-emitting elements on the transfer substrate to the side of the driving substrate, to bind two electrodes of each of the plurality of light-emitting elements to a corresponding binding region of the driving substrate.

### BRIEF DESCRIPTION OF THE DRAWINGS

In order to describe technical solutions of embodiments of the disclosure more clearly, the following will give a brief description of accompanying drawings used for describing the embodiments. Apparently, accompanying drawings described below are merely some embodiments. Those of ordinary skill in the art can also obtain other accompanying drawings based on the accompanying drawings described below without creative efforts.

FIG. 1 is a schematic diagram illustrating a layer structure of a growth substrate and light-emitting elements provided in a first embodiment of the disclosure.

FIG. 2 is a schematic structural diagram illustrating a temporary substrate of a mass transfer assembly provided in the first embodiment of the disclosure.

FIG. 3 is a schematic diagram illustrating adhering of light-emitting elements with the temporary substrate illustrated in FIG. 2.

FIG. 4 is a schematic diagram illustrating a first structure of a transfer substrate of the mass transfer assembly provided in the first embodiment of the disclosure.

FIG. 5 is a schematic diagram illustrating adhering of light-emitting elements with the transfer substrate illustrated in FIG. 4.

FIG. 6 is a schematic diagram illustrating transferring of light-emitting elements to a driving substrate from the transfer substrate illustrated in FIG. 4.

FIG. 7 is a schematic diagram illustrating a second structure of the transfer substrate of the mass transfer assembly provided in the first embodiment of the disclosure.

FIG. 8 is a schematic diagram illustrating adhering of light-emitting elements with the transfer substrate illustrated in FIG. 7.

FIG. 9 is a schematic diagram illustrating transferring of light-emitting elements to the driving substrate from the transfer substrate illustrated in FIG. 7.

FIG. 10 is a schematic diagram illustrating a layer structure of a display panel provided in a second embodiment of the disclosure.

FIG. 11 is a schematic diagram illustrating a layer structure of a display device provided in a third embodiment of the disclosure.

### DETAILED DESCRIPTION

In order to facilitate understanding of the disclosure, the disclosure will be described fully below with reference to accompanying drawings. The accompanying drawings illustrate exemplary embodiments of the disclosure. However, the disclosure may be implemented in many different forms and is not limited to the embodiments described herein. Rather, these embodiments are provided to achieve a thorough and complete understanding of disclosed contents of the disclosure.

The following descriptions of the embodiments are with reference to the attached diagrams to illustrate specific embodiments that the disclosure can be implemented. The serial numbers for the components herein, such as “first”, “second”, etc., are only used to distinguish the objects described and do not have any order or technical meaning. The “connection” and “coupling” mentioned in the disclosure, unless otherwise specified, include direct and indirect connections (couplings). The directional terms mentioned in the disclosure, such as “upper”, “lower”, “front”, “back”, “left”, “right”, “inside”, “outside”, “side”, etc., are only with reference to the directions of the attached drawings. Therefore, the directional terms used are for better and clearer explanation and understanding of the disclosure, rather than indicating or implying that the device or element referred to must have a specific orientation, be constructed and operated in a specific orientation, and therefore cannot be understood as a limitation to the disclosure.

It is to be noted that, in the description of the disclosure, unless the context clearly indicates otherwise, the terms “mounted”, “coupled”, and “connected” should be broadly understood. For example, these terms may refer to a fixed connection, a removable connection, or an integrated connection; or, may refer to a mechanical connection; or, may refer to a direct connection, an indirect connection through an intermediary, or an internal communication or interaction of two elements. For those skilled in the art, the meanings of the above terms referred to in the disclosure may be understood based on specific situations. It is to be noted that, the terms “first”, “second”, and the like used in the specification, the claims, and the accompany drawings of the disclosure are used to distinguish different objects rather than describe a particular order.

In addition, the terms “include”, “may include”, “have”, or “may have” used in the disclosure indicate existence of disclosed corresponding functions, operations, elements, etc., and do not constitute limitations on one or more additional functions, operations, elements, etc. Furthermore, the terms “include”, “comprise”, and “have” as well as variations thereof refer to presence of corresponding features, numbers, operations, elements, components, or combinations thereof disclosed in the specification, which does not exclude presence or addition of one or more other features, numbers, operations, elements, components, or combinations thereof, and are intended to cover non-exclusive inclusion. In addition, when describing the embodiments of the disclosure, the term “may” represents “one or more embodiments of the disclosure”. Moreover, the term “exemplary” is intended to refer to examples or illustrations.

Unless otherwise defined, all technical and scientific terms herein have the same meaning as commonly understood by one of ordinary skill in the technical field to which the disclosure belongs. The terms herein are merely for the purpose of describing embodiments of the disclosure, which are not intended to limit the disclosure.

In view of the above deficiencies of the related art, the disclosure provides a mass transfer assembly, a display panel, and a display device having the display panel, which aims to transfer micro LED elements on a growth substrate to a driving substrate at one time.

In order to solve the above technical problems, the disclosure provides a mass transfer assembly. The mass transfer assembly is used for transferring a plurality of light-emitting elements from a growth substrate to a driving substrate. Each of the plurality of light-emitting elements includes a light-emitting body connected with the growth substrate and two electrodes connected with the light-emitting body. The mass transfer assembly includes a temporary substrate and a transfer substrate. The temporary substrate is configured to adhere two electrodes of each of a plurality of light-emitting elements on the growth substrate, to separate the plurality of light-emitting elements from the growth substrate, such that a light-emitting body of each of the plurality of light-emitting elements is suspended. The transfer substrate has a plurality of adhesion regions, and the transfer substrate is configured to adhere, through the adhesion regions, a light-emitting body of each of a plurality of light-emitting elements on the temporary substrate, where one adhesion region adheres a light-emitting body of one light-emitting element, to separate the plurality of light-emitting elements from the temporary substrate, such that two electrodes of each of the plurality of light-emitting elements are suspended. The driving substrate has a plurality of binding regions, positions of the plurality of binding regions on the driving substrate are in one-to-one correspondence with positions of the plurality of adhesion regions on the transfer substrate. The transfer substrate is further configured to transfer the plurality of light-emitting elements to one side of the driving substrate, to bind the two electrodes of each of the plurality of light-emitting elements to a corresponding binding region of the driving substrate.

In sum, the mass transfer assembly provided in embodiments of the disclosure includes the temporary substrate and the transfer substrate, the positions of the plurality of binding regions on the driving substrate are in one-to-one correspondence with the positions of the plurality of adhesion regions on the transfer substrate, and the plurality of binding regions of the driving substrate are used for binding the light-emitting elements. As such, the plurality of light-emitting elements adhered to the transfer substrate can be transferred to the driving substrate at one time, thereby reducing workload and cost of transferring of the light-emitting elements.

In exemplary embodiments, the temporary substrate includes a first base substrate and an adhesion layer. The adhesion layer is disposed on a surface of the first base substrate. The adhesion layer is used for adhering the two electrodes of each of the plurality of light-emitting elements on the growth substrate.

In exemplary embodiments, the transfer substrate includes a second substrate, a plurality of photothermal elements, a packaging layer, a plurality of expansion media, a flexible layer, and a plurality of adhesion elements. The plurality of photothermal elements are spaced apart from one another on a surface of the second substrate. The packaging layer covers the plurality of photothermal elements on the second substrate, and the packaging layer defines a plurality of accommodating holes penetrating through the packaging layer. Each of the plurality of accommodating holes is filled with an expansion medium, and the expansion medium is in contact with the photothermal element. The flexible layer shields and covers the plurality of expansion media. The plurality of adhesion elements are disposed on a surface of the flexible layer facing away from the plurality of expansion media. A position of one expansion medium and a position of one adhesion element both correspond to a position of one adhesion region. The photothermal element is configured to receive lights to generate heat. The expansion medium is configured to receive heat conducted by the photothermal element to expand to abut against the flexible layer, and the flexible layer abuts against the adhesion element, such that the adhesion element adheres to the light-emitting body of the light-emitting element.

In exemplary embodiments, the transfer substrate includes a flat layer, a plurality of electric heating elements, a packaging layer, a plurality of expansion media, a plurality of flexible layers, and a plurality of adhesion elements. The plurality of electric heating elements are disposed on a surface of the flat layer. The packaging layer covers the plurality of electric heating elements on the flat layer, and the packaging layer defines a plurality of accommodating holes penetrating through the packaging layer. Each of the plurality of accommodating holes is filled with the expansion medium, and the expansion medium is in contact with the electric heating element. The flexible layer covers the plurality of expansion media. The plurality of adhesion elements are disposed on a surface of the flexible layer facing away from the plurality of expansion media. A position of one expansion medium and a position of one adhesion element both correspond to a position of one adhesion region. The electric heating element is configured to receive a current to generate heat. The expansion medium is configured to receive heat conducted by the electric heating element to expand to abut against the flexible layer, and the flexible layer abuts against the adhesion element, such that the adhesion element adheres to the light-emitting body of the light-emitting element.

In exemplary embodiments, the transfer substrate further includes a plurality of control transistors. Each of the plurality of control transistors has a gate, an active device, a drain, and a source. The active device is electrically connected with the drain and the source. The drain of the control transistor is further electrically connected with one electric heating element. The source of the control transistor is further electrically connected with a power-supply terminal. The gate of the control transistor is configured to receive a control signal to turn on the active device of the control transistor, to make the drain of the control transistor be electrically connected with the source of the control transistor, such that the electric heating element receives a current outputted by the power-supply terminal.

In exemplary embodiments, the transfer substrate further includes a second substrate, an insulating layer, and a passivation layer. The second substrate is disposed on one side of the flat layer facing away from the plurality of electric heating elements, and is spaced apart from the flat layer. A plurality of gates are spaced apart from one another on one side of the second substrate facing the flat layer. The insulating layer covers the plurality of gates on the second substrate. A plurality of active devices are disposed on a surface of the insulating layer facing away from the second substrate. A position of one active device corresponds to a position of one gate. The drain and the source are connected with the active device. The drain is spaced apart from the source. The passivation layer covers the plurality of active devices, the plurality of drains, and the plurality of sources on the insulating layer. The passivation layer is connected with the flat layer.

In exemplary embodiments, the flat layer defines a plurality of first vias penetrating through the flat layer, the passivation layer defines a plurality of second vias penetrating through the passivation layer, one drain is exposed from one second via, and one second via communicates with one first via. The transfer substrate further includes a plurality of connecting electrodes, one connecting electrode is accommodated in one first via and one second via which are in communication, and one connecting electrode is connected with one electric heating element and one drain.

In exemplary embodiments, the expansion medium is made of nitrogen, argon, water, or alcohol, and the flexible layer is made of polyester fiber or polyvinyl alcohol.

Based on the same inventive concept, the disclosure further provides a display panel. The display panel includes a driving substrate and a plurality of light-emitting elements disposed on one side of the driving substrate. The plurality of light-emitting elements are transferred to the driving substrate by the above mass transfer assembly.

In sum, the display panel provided in embodiments of the disclosure includes the driving substrate and the plurality of light-emitting elements, the plurality of light-emitting elements are transferred to the driving substrate by the mass transfer assembly, the mass transfer assembly includes the temporary substrate and the transfer substrate, the positions of the plurality of binding regions on the driving substrate are in one-to-one correspondence with the positions of the plurality of adhesion regions on the transfer substrate, and the plurality of binding regions of the driving substrate are used for binding the light-emitting elements. As such, the plurality of light-emitting elements adhered to the transfer substrate can be transferred to the driving substrate at one time, thereby reducing workload and cost of transferring of the light-emitting elements.

Based on the same inventive concept, the disclosure further provides a display device. The display device includes a housing and the above display panel. The display panel is received in the housing. A light-emitting side of the display panel is exposed from the housing.

In sum, the display device provided in embodiments of the disclosure includes the housing and the display panel, the display panel includes the driving substrate and the plurality of light-emitting elements, the plurality of light-emitting elements are transferred to the driving substrate by the mass transfer assembly, the mass transfer assembly includes the temporary substrate and the transfer substrate, the positions of the plurality of binding regions on the driving substrate are in one-to-one correspondence with the positions of the plurality of adhesion regions on the transfer substrate, and the plurality of binding regions of the driving substrate are used for binding the light-emitting elements. As such, the plurality of light-emitting elements adhered to the transfer substrate can be transferred to the driving substrate at one time, thereby reducing workload and cost of transferring of the light-emitting elements.

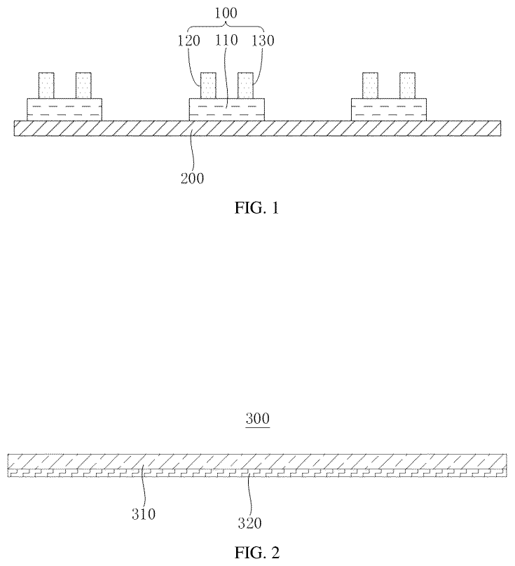

Referring to FIG. 1, FIG. 1 is a schematic diagram illustrating a layer structure of a growth substrate and light-emitting elements provided in a first embodiment of the disclosure. As illustrated in FIG. 1, multiple light-emitting elements 100 are formed on a surface of a growth substrate 200, and each light-emitting element 100 includes a light-emitting body 110 as well as a first electrode 120 and a second electrode 130 which are electrically connected with the light-emitting body 110. The light-emitting body 110 is formed on the surface of the growth substrate 200, and the first electrode 120 and the second electrode 130 each are formed on a surface of the light-emitting body 110 facing away from the growth substrate 200, such that the first electrode 120 is suspended and the second electrode 130 is suspended. The expression “the first electrode 120 is suspended” means that one end of the first electrode 120 is connected with the light-emitting body 110 while the other end of the first electrode 120 facing away from the light-emitting body 110 is not connected with other components. The expression “the second electrode 130 is suspended” means that one end of the second electrode 130 is connected with the light-emitting body 110 while the other end of the second electrode 130 facing away from the light-emitting body 110 is not connected with other components.

In exemplary embodiments of the disclosure, the light-emitting element 100 may be a micro light-emitting diode (LED).

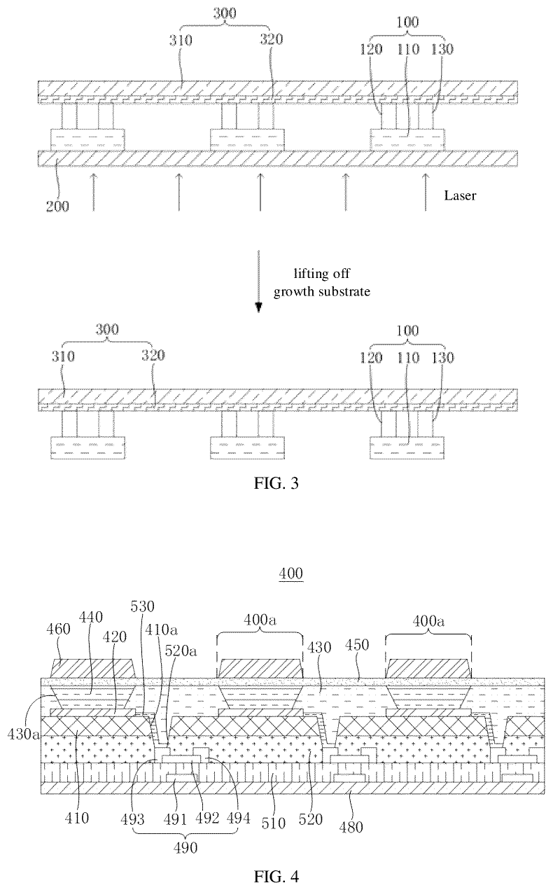

Referring to FIG. 2 and FIG. 3, FIG. 2 is a schematic structural diagram illustrating a temporary substrate of a mass transfer assembly provided in the first embodiment of the disclosure, and FIG. 3 is a schematic diagram illustrating adhering of light-emitting elements with the temporary substrate illustrated in FIG. 2. The mass transfer assembly provided in embodiments of the disclosure is used for transferring multiple light-emitting elements 100 on the growth substrate 200 to a driving substrate. The mass transfer assembly includes a temporary substrate 300. The temporary substrate 300 is aligned with the growth substrate 200, such that the first electrode 120 and the second electrode 130 of each light-emitting element 100 on the growth substrate 200 face the temporary substrate 300. The temporary substrate 300 is configured to adhere the first electrode 120 and the second electrode 130 of each light-emitting element 100 on the growth substrate 200, to separate the multiple light-emitting elements 100 from the growth substrate 200, such that the light-emitting body 110 of each light-emitting element 100 is suspended. The light-emitting body 110 being suspended means that one side of the light-emitting body 110 is connected with the first electrode 120 and the second electrode 130 while the other side of the light-emitting body 110 facing away from the first electrode 120 and the second electrode 130 is not connected with other components.

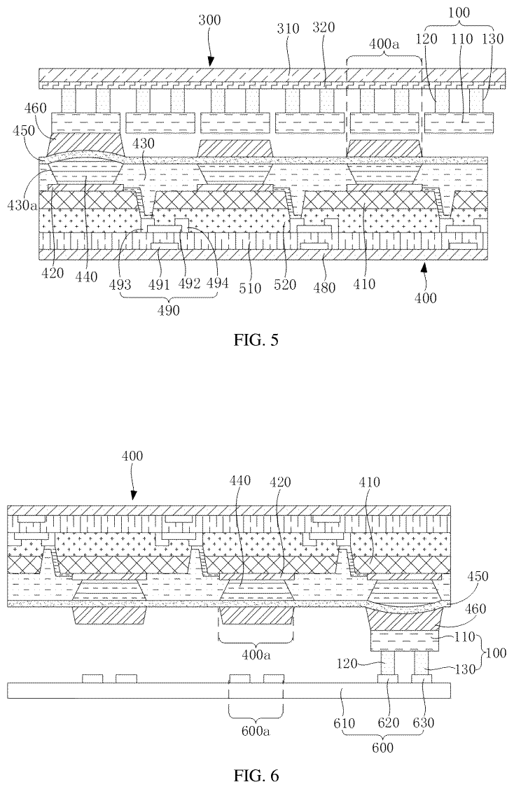

Referring to FIG. 4 and FIG. 5, FIG. 4 is a schematic diagram illustrating a first structure of a transfer substrate of the mass transfer assembly provided in the first embodiment of the disclosure, and FIG. 5 is a schematic diagram illustrating adhering of light-emitting elements with the transfer substrate illustrated in FIG. 4. The mass transfer assembly further includes a transfer substrate 400. The transfer substrate 400 has multiple adhesion regions 400a arranged in an array and spaced apart from one another. The transfer substrate 400 is aligned with the temporary substrate 300, such that the light-emitting body 110 of each light-emitting element 100 on the temporary substrate 300 faces the transfer substrate 400. The transfer substrate 400 is configured to adhere the light-emitting body 110 of each light-emitting element 100 on the temporary substrate 300, where one adhesion region 400a adheres the light-emitting body 110 of one light-emitting element 100, to separate the multiple light-emitting elements 100 from the temporary substrate 300, such that the first electrode 120 and the second electrode 130 of each light-emitting element 100 are suspended.

Referring to FIG. 6, FIG. 6 is a schematic diagram illustrating transferring of light-emitting elements to the driving substrate from the transfer substrate illustrated in FIG. 4. A driving substrate 600 illustrated in FIG. 6 has multiple binding regions 600a arranged in an array and spaced apart from one another. Positions of the multiple binding regions 600a on the driving substrate 600 are in one-to-one correspondence with positions of the multiple adhesion regions 400a on the transfer substrate 400, that is, the positions of the multiple binding regions 600a of the driving substrate 600 are in one-to-one correspondence with the positions of the multiple adhesion regions 400a of the transfer substrate 400. The transfer substrate 400 is aligned with the driving substrate 600, such that the multiple binding regions 600a coincide with the multiple adhesion regions 400a in one-to-one correspondence, and the first electrode 120 and the second electrode 130 of each light-emitting element 100 on the transfer substrate 400 face the driving substrate 600. The transfer substrate 400 is further configured to transfer the multiple light-emitting elements 100 to one side of the driving substrate 600. The driving substrate 600 fixes the first electrode 120 and the second electrode 130 of each light-emitting element 100, such that the first electrode 120 and the second electrode 130 of each light-emitting element 100 are fixed to a corresponding binding region 600a of the driving substrate 600.

It can be understood that, the multiple binding regions 600a of the driving substrate 600 are used for binding the light-emitting elements 100, and a distance between two adjacent light-emitting elements 100 on the growth substrate 200 is smaller than a distance between two adjacent binding regions 600a of the driving substrate 600. The positions of the multiple binding regions 600a on the driving substrate 600 are in one-to-one correspondence with the positions of the multiple adhesion regions 400a on the transfer substrate 400, that is, a distance between two adjacent adhesion regions 400a is consistent with the distance between two adjacent binding regions 600a. As such, multiple light-emitting elements 100 adhered to the transfer substrate 400 can be transferred to the driving substrate 600 at one time, thereby reducing workload and cost of transferring of the light-emitting elements 100. Before the first electrode 120 and the second electrode 130 of the light-emitting element 100 are bound to the driving substrate 600, the first electrode 120 and the second electrode 130 of each light-emitting element 100 are suspended by sequentially using the temporary substrate 300 and the transfer substrate 400, and then the first electrode 120 and the second electrode 130 of each light-emitting element 100 are in contact with the driving substrate 600 for binding.

In embodiments of the disclosure, referring to FIG. 2 and FIG. 3, the temporary substrate 300 includes a first base substrate 310 and an adhesion layer 320, and the adhesion layer 320 is disposed on a surface of the first base substrate 310. The temporary substrate 300 is aligned with the growth substrate 200, the adhesion layer 320 of the temporary substrate 300 faces the growth substrate 200, the first electrode 120 and the second electrode 130 of each light-emitting element 100 on the growth substrate 200 face the adhesion layer 320 of the temporary substrate 300, and the adhesion layer 320 is connected with the first electrode 120 and the second electrode 130 of the multiple light-emitting elements 100. The adhesion layer 320 is used for adhering the first electrode 120 and the second electrode 130 of each light-emitting element 100.

It can be understood that, the light-emitting body 110 of each light-emitting element 100 may be separated from the growth substrate 200 through a laser lift off (LLO) process, such that the light-emitting body 110 of each light-emitting element 100 is suspended. In exemplary embodiments of the disclosure, the adhesion layer 320 is an adhesive glue.

In embodiments of the disclosure, referring to FIG. 4, the transfer substrate 400 includes a flat layer 410, multiple electric heating elements 420, a packaging layer 430, and multiple expansion media 440. The multiple electric heating elements 420 are arranged in an array and spaced apart from one another on a surface of the flat layer 410. The position of one electric heating element 420 corresponds to the position of one adhesion region 400a, that is, an orthographic projection of one electric heating element 420 on the flat layer 410 falls into an orthographic projection of one adhesion region 400a on the flat layer 410. The packaging layer 430 is disposed on a surface of the multiple electric heating elements 420 facing away from the flat layer 410 and covers the flat layer 410, that is, the packaging layer 430 covers the multiple electric heating elements 420 on the flat layer 410. The packaging layer 430 defines multiple accommodating holes 430a penetrating through the packaging layer 430. The position of one accommodating hole 430a corresponds to the position of one electric heating element 420, that is, an orthographic projection of one accommodating hole 430a on the flat layer 410 overlaps an orthographic projection of one electric heating element 420 on the flat layer 410, such that a portion of the electric heating element 420 is exposed to the outside of an opening of the accommodating hole 430a facing the electric heating element 420. Each of the multiple accommodating holes 430a is filled with an expansion medium 440, and the expansion medium 440 is in contact with the electric heating element 420. The flat layer 410 provides a flat surface, such that the multiple electric heating elements 420 are located on the same plane. The packaging layer 430 provides the multiple accommodating holes 430a for accommodating the expansion media 440.

In embodiments of the disclosure, referring to FIG. 4, the transfer substrate 400 further includes multiple flexible layers 450 and multiple adhesion elements 460. The flexible layer 450 is disposed on a surface of the packaging layer 430 facing away from the flat layer 410 and covers the multiple expansion media 440. The multiple adhesion elements 460 are disposed on a surface of the flexible layer 450 facing away from the multiple expansion media 440. The position of one adhesion element 460 corresponds to the position of one expansion medium 440, that is, an orthographic projection of one adhesion element 460 on the flat layer 410 overlaps an orthographic projection of one expansion medium 440 on the flat layer 410, and the orthographic projection of one adhesion element 460 on the flat layer 410 overlaps an orthographic projection of one adhesion region 400a on the flat layer 410. Referring to FIG. 5, the transfer substrate 400 is aligned with the temporary substrate 300, the multiple adhesion elements 460 of the transfer substrate 400 face the temporary substrate 300, the light-emitting body 110 of each of multiple light-emitting elements 100 on the temporary substrate 300 faces the transfer substrate 400, and the adhesion elements 460 is spaced apart from the light-emitting elements 100 by a preset distance. The electric heating element 420 is configured to generate heat after receiving a current. Since the expansion medium 440 is in contact with the electric heating element 420, the expansion medium 440 can expand to abut against the flexible layer 450 after receiving the heat conducted by the electric heating element 420, such that a portion of the flexible layer 450 connected with the expansion medium 440 protrudes toward one side of the flexible layer 450 facing away from the packaging layer 430 (that is, protruding toward the adhesion element 460) to abut against the adhesion element 460. A portion of the expansion medium 440 protrudes toward one side of the flexible layer 450 facing away from the packaging layer 430, such that the height of the adhesion element 460 increases. The adhesion element 460 with the increased height is configured to adhere the light-emitting body 110 of the light-emitting element 100. The connection strength between the adhesion element 460 and the light-emitting element 100 is greater than the connection strength between the adhesion layer 320 and the light-emitting element 100. A surface of the flat layer 410 facing the packaging layer 430 is a reference plane for the height, and the height increases in a direction in which the packaging layer 430 faces away from the flat layer 410.

It can be understood that, after the electric heating element 420 receives the current, the adhesion element 460 corresponding to the position of the electric heating element 420 can adhere the light-emitting element 100, and the position of the adhesion element 460 corresponds to the position of the adhesion region 400a, as such, the light-emitting element(s) 100 adhered to the transfer substrate 400 is only located in the adhesion region 400a. The multiple electric heating elements 420 can selectively receive the current, such that some of the multiple electric heating elements 420 receive the current while the remaining electric heating elements 420 do not receive the current, and further, some of the multiple adhesion elements 460 adhere the light-emitting body 110 of the light-emitting element 100 while the remaining adhesion elements 460 do not adhere the light-emitting element 100, that is, the multiple adhesion elements 460 can selectively adhere the light-emitting elements 100, as such, the adhesion element(s) 460 located at a specified position(s) of the transfer substrate 400 adheres the light-emitting element(s) 100 on the temporary substrate 300. Since the connection strength between the adhesion element 460 and the light-emitting element 100 is greater than the connection strength between the adhesion layer 320 and the light-emitting element 100, the light-emitting element(s) 100 adhered to the transfer substrate 400 can be separated from the temporary substrate 300 under action of an external force.

It is to be noted that, the driving substrate 600 and multiple light-emitting elements 100 on the driving substrate 600 are part of a display panel. The multiple light-emitting elements 100 on the driving substrate 600 have three types, that is, multiple first light-emitting elements for emitting red lights, multiple second light-emitting elements for emitting green lights, and multiple third light-emitting elements for emitting blue lights. The three types of light-emitting elements (i.e., the multiple first light-emitting elements, the multiple second light-emitting elements, and the multiple third light-emitting elements) may be respectively formed on different growth substrates 200. By selectively adhering light-emitting elements 100 with the multiple adhesion elements 460, the transfer substrate 400 can adhere the multiple first light-emitting elements, the multiple second light-emitting elements, and the multiple third light-emitting elements at the same time, and then the transfer substrate 400 can transfer the multiple first light-emitting elements, the multiple second light-emitting elements, and the multiple third light-emitting elements to the driving substrate 600 at one time, thereby improving efficiency of mass transfer. Furthermore, if a certain light-emitting element 100 on the growth substrate 200 is damaged, the damaged light-emitting element 100 will be adhered to the temporary substrate 300, but an adhesion element 460 corresponding to the position of the damaged light-emitting element 100 will not adhere the damaged light-emitting element 100, thereby avoiding the damaged light-emitting element 100 from being transferred to the driving substrate 600.

In embodiments of the disclosure, referring to FIG. 6, the driving substrate 600 includes a driving circuit layer 610, multiple first conductive elements 620, and multiple second conductive elements 630. The multiple first conductive elements 620 and the multiple second conductive elements 630 are disposed on one side of the driving circuit layer 610. One first conductive element 620 and one second conductive element 630 are disposed in one binding region 600a. The transfer substrate 400 is aligned with the driving substrate 600, such that multiple binding regions 600a coincide with multiple adhesion regions 400a in one-to-one correspondence, the first electrode 120 and the second electrode 130 of each light-emitting element 100 on the transfer substrate 400 face the driving substrate 600, and the multiple first conductive elements 620 and the multiple second conductive elements 630 of the driving substrate 600 face the transfer substrate 400. The first electrode 120 of the light-emitting element 100 is in contact with the first conductive element 620, and the second electrode 130 of the light-emitting element 100 is in contact with the second conductive element 630, such that the first electrode 120 is bound to the first conductive element 620 and the second electrode 130 is bound to the second conductive element 630. The connection strength between the driving substrate 600 and the light-emitting element 100 is greater than the connection strength between the transfer substrate 400 and the light-emitting element 100, such that the light-emitting element 100 fixed to the driving substrate 600 can be separated from the transfer substrate 400 under action of an external force.

It can be understood that, as illustrated in FIG. 6, an electric heating element 420 is configured to receive a current, and accordingly, the height of a light-emitting element 100 corresponding to the position of the electric heating element 420 increases, such that the light-emitting element 100 corresponding to the position of the electric heating element 420 moves toward the driving substrate 600 and is bound to the driving substrate 600. The multiple electric heating elements 420 can selectively receive the current, such that the height of some light-emitting elements 100 adhered to the transfer substrate 400 increases, and the light-emitting elements 100 with the increased height is in contact with and bound to the driving substrate 600, while the light-emitting element(s) 100 of which the height is not increased is not in contact with the driving substrate 600 and is therefore not bound. As such, by making the multiple electric heating elements 420 receive the current selectively, the light-emitting element 100 can be bound to the binding region 600a at a specified position of the driving substrate 600.

It is to be noted that, the light-emitting elements 100 adhered to the transfer substrate 400 may also be of the same type, that is, the light-emitting elements 100 adhered to the transfer substrate 400 may all be the first light-emitting elements, or may all be the second light-emitting elements, or may all be the third light-emitting elements, and the multiple light-emitting elements 100 on the driving substrate 600 include multiple first light-emitting elements, multiple second light-emitting elements, and multiple third light-emitting elements. The multiple electric heating elements 420 can selectively receive the current, such that the height of the light-emitting element 100 at a specified position among multiple light-emitting elements 100 of the same type on the transfer substrate 400 increases, to make the light-emitting elements 100 of the same type be bound to the binding regions 600a at the specified positions of the driving substrate 600.

In exemplary embodiments, after the light-emitting elements 100 are transferred to and bound to the driving substrate 600 from the transfer substrate 400, the multiple electric heating elements 420 stop receiving the current, and accordingly, the temperature of the expansion medium 440 drops to the room temperature, and the volume of the expansion medium 440 returns to its original volume for a next transfer.

In exemplary embodiments, the material of the flat layer 410 may include a polyimide (PI) film or a polymethyl methacrylate (PMMA), which is not limited in the disclosure. The material of the expansion medium 440 may include nitrogen, argon, water, alcohol, or other inert gases that expand when heated, which is not limited in the disclosure. The electric heating element 420, the packaging layer 430, and the flexible layer 450 cooperate to seal the expansion medium 440 filled in the accommodating hole 430a. The material of the flexible layer 450 may include a polyester film (PET), a polyvinyl alcohol (PVA) film, or other organic film layers with a good deformation property, which is not limited in the disclosure. The adhesion element 460 may be an adhesive glue.

In embodiments of the disclosure, referring to FIG. 4 and FIG. 5, the transfer substrate 400 further includes a second substrate 480, multiple control transistors 490, an insulating layer 510, and a passivation layer 520. The second substrate 480 is disposed on one side of the flat layer 410 facing away from the multiple electric heating elements 420 and is spaced apart from the flat layer 410. Each control transistor 490 includes a gate 491, an active device 492, a drain 493, and a source 494. Multiple gates 491 are spaced apart from one another on one side of the second substrate 480 facing the flat layer 410. An orthographic projection of one electric heating element 420 on the second substrate 480 is adjacent to an orthographic projection of one gate 491 on the second substrate 480. The insulating layer 510 is disposed on the surface of each gate 491 facing away from the second substrate 480 and covers the second substrate 480, that is, the insulating layer 510 covers the multiple gates 491 on the second substrate 480. Multiple active devices 492 are disposed on a surface of the insulating layer 510 facing away from the second substrate 480. The position of one active device 492 corresponds to the position of one gate 491, that is, an orthographic projection of one active device 492 on the second substrate 480 overlaps or partially overlaps an orthographic projection of one gate 491 on the second substrate 480. The drain 493 and the source 494 are disposed on a portion of circumference of the active device 492 and a portion of a surface of the active device 492 facing away from the insulating layer 510, and the drain 493 is spaced apart from the source 494. The active device 492 is electrically connected with the drain 493 and the source 494. The passivation layer 520 is disposed on a surface of the insulating layer 510 facing away from the second substrate 480, and covers the multiple active devices 492, the multiple drains 493, and the multiple sources 494, that is, the passivation layer 520 covers the multiple active devices 492, the multiple drains 493, and the multiple sources 494 on the insulating layer 510. A surface of the passivation layer 520 facing away from the insulating layer 510 is connected with a surface of the flat layer 410 facing away from the multiple electric heating elements 420. The insulating layer 510 is used for insulating the gate 491 from the active device 492. The passivation layer 520 is used for isolating the active device 492, the drain 493, and the source 494, to prevent impurities such as water and oxygen from entering the active device 492, the drain 493, and the source 494. The drain 493 is electrically connected with the electric heating element 420, and the source 494 is electrically connected with a power-supply terminal for providing a current to the electric heating element 420. The gate 491 is configured to receive a control signal to turn on the active device 492, to make the drain 493 and the source 494 conductive through the active device 492, such that the power-supply terminal can output a current to the electric heating element 420.

It can be understood that, if the gate 491 of the control transistor 490 receives the control signal, the electric heating element 420 electrically connected with the drain 493 of the control transistor 490 receives the current. If no control signal is received by the gate 491 of the control transistor 490, no current is received by the electric heating element 420 electrically connected with the drain 493 of the control transistor 490. As such, the multiple electric heating elements 420 can selectively receive the current.

In exemplary embodiments, the control transistor 490 may be a thin-film transistor (TFT) or a metal oxide semiconductor field effect transistor (MOSFET). The material of the gate 491, the material of the drain 493, and the material of the source 494 each may include metal materials such as aluminum, molybdenum, or copper. The material of the active device 492 may include single crystal silicon, polycrystalline silicon, or indium gallium zinc oxide, etc. The material of the insulating layer 510 and the material of the passivation layer 520 each may include silicon nitride or silicon oxide, etc. The disclosure does not limit the material of the above structure.

In exemplary embodiments, referring to FIG. 4, the flat layer 410 defines multiple first vias 410a penetrating through the flat layer 410. The position of one first via 410a corresponds to the position of one drain 493, that is, an orthographic projection of one first via 410a on the second substrate 480 overlaps or partially overlaps an orthographic projection of one drain 493 on the second substrate 480. The passivation layer 520 defines multiple second vias 520a penetrating through the passivation layer 520. The position of one second via 520a corresponds to the position of one drain 493, that is, an orthographic projection of one second via 520a on the second substrate 480 overlaps or partially overlaps an orthographic projection of one drain 493 on the second substrate 480. A portion of the drain 493 is exposed from one second via 520a, and one second via 520a communicates with one first via 410a, where the expression “communicate with” means connecting and communicating. The transfer substrate 400 further includes multiple connecting electrodes 530. A portion of one connecting electrode 530 is accommodated in a first via 410a and a second via 520a and is connected with the drain 493, and another portion of the connecting electrode 530 is disposed on a portion of a surface of the flat layer 410 facing away from the passivation layer 520 and is connected with an electric heating element 420, such that the electric heating element 420 is electrically connected with the drain 493. That is, one end of the connecting electrode 530 is connected with the electric heating element 420, and another end of the connecting electrode 530 extends through the first via 410a and the second via 520a to be connected to the drain 493, such that the electric heating element 420 is electrically connected with the drain 493 through the connecting electrode 530. A portion of the packaging layer 430 is filled in the first vias 410a and the second vias 520a.

In exemplary embodiments, the material of the connecting electrode 530 includes indium tin oxide (ITO).

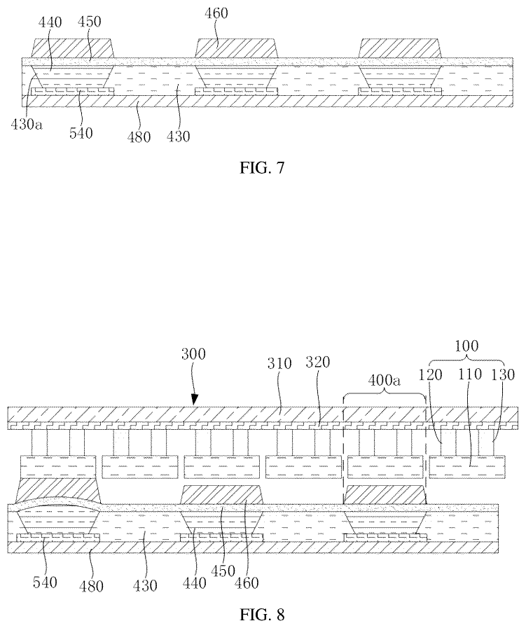

Referring to FIG. 7, FIG. 7 is a schematic diagram illustrating a second structure of the transfer substrate of the mass transfer assembly provided in the first embodiment of the disclosure. The difference between the transfer substrate of the second structure and the transfer substrate of the first structure is that: the transfer substrate of the second structure does not include the flat layer 410, the multiple electric heating elements 420, the multiple control transistors 490, the insulating layer 510, and the multiple passivation layers 520. The transfer substrate of the second structure includes the second substrate 480, multiple photothermal elements 540, the packaging layer 430, the multiple expansion media 440, the flexible layer 450, and the multiple adhesion elements 460. For details of the structures of the transfer substrate of the second structure and the transfer substrate of the first structure, reference can be made to the relevant description of the transfer substrate of the first structure, which will not be repeated herein.

Specifically, referring to FIG. 7, the multiple photothermal elements 540 are disposed on a surface of the second substrate 480, and the multiple photothermal elements 540 are spaced apart from one another. The packaging layer 430 is disposed on the surface of each of the multiple photothermal elements 540 facing away from the second substrate 480, and covers a surface of the second substrate 480 on which the multiple photothermal elements 540 are disposed, that is, the packaging layer 430 covers the multiple photothermal elements 540 on the second substrate 480. The packaging layer 430 defines multiple accommodating holes 430a penetrating through the packaging layer 430. Each of the multiple accommodating holes 430a is filled with the expansion medium 440. The flexible layer 450 is disposed on a surface of the packaging layer 430 facing away from the second substrate 480, and shields and covers the multiple expansion media 440. The multiple adhesion elements 460 are disposed on a surface of the flexible layer 450 facing away from the multiple expansion media 440. The position of one adhesion element 460 corresponds to the position of one expansion medium 440, that is, an orthographic projection of one adhesion element 460 on the second substrate 480 overlaps or partially overlaps an orthographic projection of one expansion medium 440 on the second substrate 480.

In embodiments of the disclosure, referring to FIG. 8, FIG. 8 is a schematic diagram illustrating adhering of light-emitting elements with the transfer substrate illustrated in FIG. 7. The photothermal element 540 is configured to generate heat after receiving lights. Since the expansion medium 440 is in contact with the photothermal element 540, the expansion medium 440 can expand to abut against the flexible layer 450 after receiving the heat conducted by the photothermal element 540, such that a portion of the flexible layer 450 connected with the expansion medium 440 protrudes toward one side of the flexible layer 450 facing away from the packaging layer 430 (i.e., protruding toward the adhesion element 460) to abut against the adhesion element 460. A portion of the expansion medium 440 protrudes toward the side of the flexible layer 450 facing away from the packaging layer 430, such that the height of the adhesion element 460 increases. The adhesion element 460 with the increased height is configured to adhere the light-emitting body 110 of the light-emitting element 100. Regarding the height, a surface of the second substrate 480 facing the packaging layer 430 is taken as a reference plane, and a direction in which the packaging layer 430 faces away from the second substrate 480 is a direction in which the height increases. The multiple photothermal elements 540 can selectively receive lights, such that the multiple adhesion elements 460 can selectively adhere the light-emitting body 110 of the light-emitting element 100.

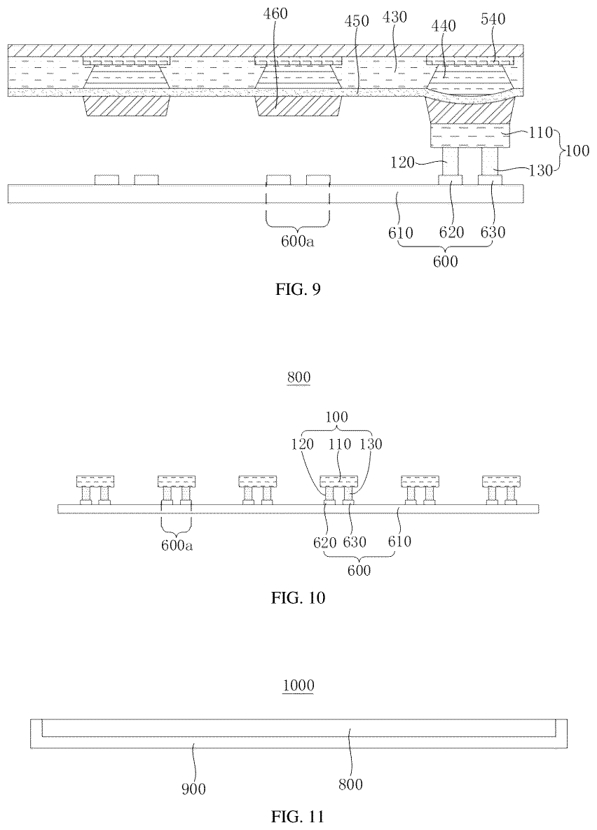

In embodiments of the disclosure, referring to FIG. 9, FIG. 9 is a schematic diagram illustrating transferring of light-emitting elements to the driving substrate from the transfer substrate illustrated in FIG. 7. The photothermal element 540 is configured to receive lights, and the height of a light-emitting element 100 corresponding to the position of the photothermal element 540 increases, such that the light-emitting element 100 corresponding to the position of the photothermal element 540 moves toward the driving substrate 600 and is bound to the driving substrate 600. The multiple photothermal elements 540 can selectively receive lights, such that the height of some light-emitting elements 100 adhered to the transfer substrate 400 increases, and the light-emitting elements 100 of which the height is increased is in contact with and bound to the driving substrate 600, while the light-emitting element(s) 100 of which the height is not increased is not in contact with the driving substrate 600 and is therefore not bound. As such, by making the multiple photothermal elements 540 selectively receive lights, the light-emitting element 100 can be bound to the binding region 600a at a specified position of the driving substrate 600.

In exemplary embodiments, the material of the photothermal element 540 includes PI containing carbon powder, PMMA containing carbon powder, or metal chromium, which is not limited in the disclosure.

In sum, the mass transfer assembly provided in embodiments of the disclosure includes the temporary substrate 300 and the transfer substrate 400. The temporary substrate 300 is configured to adhere the first electrode 120 and the second electrode 130 of each light-emitting element 100 on the growth substrate 200, to separate the multiple light-emitting elements 100 from the growth substrate 200, such that the light-emitting body 110 of each light-emitting element 100 is suspended. The transfer substrate 400 has multiple adhesion regions 400a arranged in an array and spaced apart from one another. The transfer substrate 400 is configured to adhere the light-emitting body 110 of each light-emitting element 100 on the temporary substrate 300, where the light-emitting body 110 of one light-emitting element 100 is adhered to one adhesion region 400a, to separate the multiple light-emitting elements 100 from the temporary substrate 300, such that the first electrode 120 and the second electrode 130 of each of the multiple light-emitting elements 100 are suspended. The driving substrate 600 has multiple binding regions 600a arranged in an array and spaced apart from one another, and positions of the multiple binding regions 600a are in one-to-one correspondence with positions of the multiple adhesion regions 400a. The transfer substrate 400 is further configured to transfer the multiple light-emitting elements 100 to one side of the driving substrate 600. The driving substrate 600 fixes the first electrode 120 and the second electrode 130 of each of the multiple light-emitting elements 100, such that the first electrode 120 and the second electrode 130 of each light-emitting element 100 are fixed to a corresponding binding region 600a of the driving substrate 600. As such, positions of the multiple binding regions 600a of the driving substrate 600 are in one-to-one correspondence with positions of the multiple adhesion regions 400a of the transfer substrate 400, that is, a distance between two adjacent adhesion regions 400a is idential with a distance between two adjacent binding regions 600a, and thus, the multiple light-emitting elements 100 adhered to the transfer substrate 400 can be transferred to the driving substrate 600 at one time, thereby reducing workload and cost of transferring of the light-emitting elements 100.

Based on the same inventive concept, the second embodiment of the disclosure provides a display panel. Referring to FIG. 10, FIG. 10 is a schematic diagram illustrating a layer structure of a display panel provided in the second embodiment of the disclosure. A display panel 800 provided in embodiments of the disclosure includes a driving substrate 600 and multiple light-emitting elements 100. The multiple light-emitting elements 100 are arranged on one side of the driving substrate 600 and are electrically connected with the driving substrate 600. The multiple light-emitting elements 100 are transferred to the driving substrate 600 by the above mass transfer assembly. The driving substrate 600 is configured to transmit an electrical signal to the multiple light-emitting elements 100 to control the multiple light-emitting elements 100 to emit lights.

In exemplary embodiments, the first electrode 120 of each of the multiple light-emitting elements 100 is bound to one first conductive element 620 of the driving substrate 600, such that the first electrode 120 is electrically connected with the first conductive element 620. The second electrode 130 of each of the light-emitting elements 100 is bound to one second conductive elements 630 of the driving substrate 600, such that the second electrode 130 is electrically connected with the second conductive element 630.

In exemplary embodiments, the display panel 800 further includes multiple sub-pixel regions for emitting lights, and the position of one sub-pixel region corresponds to the position of one light-emitting element 100, that is, the position of one sub-pixel region corresponds to the position of one binding region 600a of the driving substrate 600.

It can be understood that, the display panel 800 is applicable to an electronic device having functions such as personal digital assistants (PDA) and/or music players, for example, a mobile phone, a tablet computer, a wearable electronic device with a wireless communication function (e.g., a smart watch), etc. The above electronic device may also be other electronic devices, such as a laptop computer with a touch-sensitive surface (e.g., a touch panel), etc. In some embodiments, the electronic device may have a communication function, that is, the electronic device can establish communication with a network through the second-generation (2G) mobile phone communication technology specifications, the third-generation (3G) mobile phone communication technology specifications, the fourth-generation (4G) mobile phone communication technology specifications, the fifth-generation (5G) mobile phone communication technology specifications, the sixth-generation (6G) mobile phone communication technology specifications, a wireless local area network (W-LAN), or a communication method that may appear in the future. For the sake of simplicity, embodiments of the disclosure are not further limited.

Based on the same inventive concept, embodiments of the disclosure further provide a display device. Referring to FIG. 11, FIG. 11 is a schematic diagram illustrating a layer structure of a display device provided in a third embodiment of the disclosure. A display device 1000 provided in embodiments of the disclosure includes a housing 900 and the above display panel 800. The display panel 800 is received in the housing 900. A light-emitting side of the display panel 800 is exposed from the housing 900.

It can be understood that, the display device 1000 is applicable to an electronic device, which includes, but not limited to, a television, a tablet computer, a laptop computer, a desktop computer, a mobile phone, a vehicle-mounted display, a smart watch, a smart bracelet, smart glasses, etc. According to embodiments of the disclosure, the type of the display device 1000 is not limited, and those skilled in the art may make corresponding designs according to a specific use requirement of the display device 1000, which will not be repeated herein.

In exemplary embodiments, the display device 1000 may further include other necessary components and parts such as a power board, a high voltage board, and a key control board, and those skilled in the art may make corresponding supplements according to the specific type and actual functions of the display device 1000, which will not be repeated herein.

In other embodiments of the disclosure, the display device 1000 may further include a processor and a memory. The processor is electrically connected with the display panel 800 and is configured to control display of the display panel 800. The memory is electrically connected with the processor and is used to store program codes required for running of the processor, to control display contents of the display panel 800, etc.

In exemplary embodiments, the memory may be a volatile memory, such as a random access memory (RAM). The memory may also be a non-volatile memory (NVM), such as a read-only memory (ROM), a flash memory (FM), a hard disk drive (HDD), or a solid-state drive (SSD). The memory may also be a combination of the above-mentioned types of memory.

In exemplary embodiments, the processor includes one or more general-purpose processors, where a general-purpose processor can be any type of device capable of processing electronic instructions, including a central processing unit (CPU), a microprocessor, a microcontroller, a main processor, a controller, etc. The processor is configured to execute various types of digital storage instructions, such as software or firmware programs stored in the memory, which enables a computing device to provide a wide variety of services.

It is to be understood that, the terms “first”, “second”, etc. are used for descriptive purposes only, and should not be understood as indicating or implying relative importance or implicitly indicating the number of technical features indicated. Thus, features defined as “first” or “second” may explicitly or implicitly include one or more of the features. In the description of embodiments of the disclosure, the meaning of “plurality/multiple” refers to two or more, unless otherwise clearly and specifically defined.

In the description of the specification, the description with reference to the terms “one embodiment”, “some embodiments”, “illustrative embodiments”, “examples”, “specific examples”, “some examples”, or the like means that specific features, structures, or characteristics described in conjunction with embodiments or examples are included in at least one embodiment or example of the disclosure. In the specification, the schematic representation of the above terms does not necessarily refer to the same embodiment or example. Moreover, the specific features, structures, or characteristics described may be combined in any one or more embodiments or examples in a suitable manner.

It should be understood that, the application of the disclosure is not limited to the foregoing exemplary embodiments. Those of ordinary skill in the art may make improvements or equivalent substitutions to the disclosure according to the above descriptions, and all these improvements and equivalent substitutions, however, shall all be encompassed within the protection scope of the appended claims of the disclosure. Those of ordinary skill in the art can understand that, all or part of the processes of the above embodiments can be implemented, and equivalent changes made according to the claims of the disclosure are still within the scope of the disclosure.

What is claimed is:

1. A mass transfer assembly for transferring a plurality of light-emitting elements from a growth substrate to a driving substrate, each of the plurality of light-emitting elements comprising a light-emitting body initially connected with the growth substrate and two electrodes connected with the light-emitting body, the mass transfer assembly comprising:
a temporary substrate, wherein the temporary substrate is configured to adhere two electrodes of each of a plurality of light-emitting elements on the growth substrate, to separate the plurality of light-emitting elements from the growth substrate, such that a light-emitting body of each of the plurality of light-emitting elements is suspended; and
a transfer substrate having a plurality of adhesion regions, wherein the transfer substrate is configured to adhere, through the adhesion regions, a light-emitting body of each of a plurality of light-emitting elements on the temporary substrate, to separate the plurality of light-emitting elements from the temporary substrate, such that two electrodes of each of the plurality of light-emitting elements are suspended; wherein one adhesion region adheres a light-emitting body of one light-emitting element; wherein positions of the plurality of adhesion regions on the transfer substrate are in one-to-one correspondence with positions of a plurality of binding regions on the driving substrate; wherein the transfer substrate is further configured to transfer a plurality of light-emitting elements on the transfer substrate to one side of the driving substrate, to bind two electrodes of each of the plurality of light-emitting elements to a corresponding binding region of the driving substrate.

2. The mass transfer assembly of claim 1, wherein the temporary substrate comprises a first base substrate and an adhesion layer, the adhesion layer is disposed on a surface of the first base substrate, and the adhesion layer is used for adhering the two electrodes of each of the plurality of light-emitting elements on the growth substrate.

3. The mass transfer assembly of claim 1, wherein the transfer substrate comprises a second substrate, a plurality of photothermal elements, a packaging layer, a plurality of expansion media, a flexible layer, and a plurality of adhesion elements, wherein
the plurality of photothermal elements are spaced apart from one another on a surface of the second substrate;
the packaging layer covers the plurality of photothermal elements on the second substrate, and the packaging layer defines a plurality of accommodating holes penetrating through the packaging layer;
each of the plurality of accommodating holes is filled with an expansion medium, and the expansion medium is in contact with the photothermal element;
the flexible layer shields and covers the plurality of expansion media, the plurality of adhesion elements are disposed on a surface of the flexible layer facing away from the plurality of expansion media, and a position of one expansion medium and a position of one adhesion element both correspond to a position of one adhesion region;
the photothermal element is configured to receive lights to generate heat; and
the expansion medium is configured to receive heat conducted by the photothermal element to expand to abut against the flexible layer, and the flexible layer abuts against the adhesion element, such that the adhesion element adheres to the light-emitting body of the light-emitting element.

4. The mass transfer assembly of claim 1, wherein the transfer substrate comprises a flat layer, a plurality of electric heating elements, a packaging layer, a plurality of expansion media, a plurality of flexible layers, and a plurality of adhesion elements, wherein
the plurality of electric heating elements are disposed on a surface of the flat layer;
the packaging layer covers the plurality of electric heating elements on the flat layer, and the packaging layer defines a plurality of accommodating holes penetrating through the packaging layer;
each of the plurality of accommodating holes is filled with the expansion medium, and the expansion medium is in contact with the electric heating element;
the flexible layer covers the plurality of expansion media, the plurality of adhesion elements are disposed on a surface of the flexible layer facing away from the plurality of expansion media, and a position of one expansion medium and a position of one adhesion element both correspond to a position of one adhesion region;
the electric heating element is configured to receive a current to generate heat; and
the expansion medium is configured to receive heat conducted by the electric heating element to expand to abut against the flexible layer, and the flexible layer abuts against the adhesion element, such that the adhesion element adheres to the light-emitting body of the light-emitting element.

5. The mass transfer assembly of claim 4, wherein the transfer substrate further comprises a plurality of control transistors, wherein
each of the plurality of control transistors has a gate, an active device, a drain, and a source, and the active device is electrically connected with the drain and the source;
the drain of the control transistor is further electrically connected with one electric heating element;
the source of the control transistor is further electrically connected with a power-supply terminal; and
the gate of the control transistor is configured to receive a control signal to turn on the active device of the control transistor, to make the drain of the control transistor be electrically connected with the source of the control transistor, such that the electric heating element receives a current outputted by the power-supply terminal.

6. The mass transfer assembly of claim 5, wherein the transfer substrate further comprises a second substrate, an insulating layer, and a passivation layer, wherein
the second substrate is disposed on one side of the flat layer facing away from the plurality of electric heating elements and is spaced apart from the flat layer;
gates of the plurality of control transistors are spaced apart from one another on one side of the second substrate facing the flat layer;
the insulating layer covers the gates of the plurality of control transistors on the second substrate;
active devices of the plurality of control transistors are disposed on a surface of the insulating layer facing away from the second substrate, a position of one active device corresponds to a position of one gate, the drain and the source are connected with the active device, and the drain is spaced apart from the source; and
the passivation layer covers the active devices, drains, and sources of the plurality of control transistors on the insulating layer, and the passivation layer is connected with the flat layer.

7. The mass transfer assembly of claim 6, wherein
the flat layer defines a plurality of first vias penetrating through the flat layer, the passivation layer defines a plurality of second vias penetrating through the passivation layer, one drain is exposed from one second via, and one second via communicates with one first via; and
the transfer substrate further comprises a plurality of connecting electrodes, one connecting electrode is accommodated in one first via and one second via which are in communication, and one connecting electrode is connected with one electric heating element and one drain.

8. The mass transfer assembly of claim 3, wherein the expansion medium is made of nitrogen, argon, water, or alcohol, and the flexible layer is made of polyester fiber or polyvinyl alcohol.

9. The mass transfer assembly of claim 4, wherein the expansion medium is made of nitrogen, argon, water, or alcohol, and the flexible layer is made of polyester fiber or polyvinyl alcohol.

10. A display panel, comprising a driving substrate and a plurality of light-emitting elements disposed on one side of the driving substrate, wherein the plurality of light-emitting elements are transferred by a mass transfer assembly from a growth substrate to the driving substrate, each of the plurality of light-emitting elements comprises a light-emitting body initially connected with the growth substrate and two electrodes connected with the light-emitting body, and the mass transfer assembly comprises:
a temporary substrate, wherein the temporary substrate is configured to adhere two electrodes of each of a plurality of light-emitting elements on the growth substrate, to separate the plurality of light-emitting elements from the growth substrate, such that a light-emitting body of each of the plurality of light-emitting elements is suspended; and
a transfer substrate having a plurality of adhesion regions, wherein the transfer substrate is configured to adhere, through the adhesion regions, a light-emitting body of each of a plurality of light-emitting elements on the temporary substrate, to separate the plurality of light-emitting elements from the temporary substrate, such that two electrodes of each of the plurality of light-emitting elements are suspended; wherein one adhesion region adheres a light-emitting body of one light-emitting element; wherein positions of the plurality of adhesion regions on the transfer substrate are in one-to-one correspondence with positions of a plurality of binding regions on the driving substrate; wherein the transfer substrate is further configured to transfer a plurality of light-emitting elements on the transfer substrate to the side of the driving substrate, to bind two electrodes of each of the plurality of light-emitting elements to a corresponding binding region of the driving substrate.

11. The display panel of claim 10, wherein the temporary substrate comprises a first base substrate and an adhesion layer, the adhesion layer is disposed on a surface of the first base substrate, and the adhesion layer is used for adhering the two electrodes of each of the plurality of light-emitting elements on the growth substrate.

12. The display panel of claim 10, wherein the transfer substrate comprises a second substrate, a plurality of photothermal elements, a packaging layer, a plurality of expansion media, a flexible layer, and a plurality of adhesion elements, wherein
the plurality of photothermal elements are spaced apart from one another on a surface of the second substrate;
the packaging layer covers the plurality of photothermal elements on the second substrate, and the packaging layer defines a plurality of accommodating holes penetrating through the packaging layer;
each of the plurality of accommodating holes is filled with an expansion medium, and the expansion medium is in contact with the photothermal element;
the flexible layer shields and covers the plurality of expansion media, the plurality of adhesion elements are disposed on a surface of the flexible layer facing away from the plurality of expansion media, and a position of one expansion medium and a position of one adhesion element both correspond to a position of one adhesion region;
the photothermal element is configured to receive lights to generate heat; and
the expansion medium is configured to receive heat conducted by the photothermal element to expand to abut against the flexible layer, and the flexible layer abuts against the adhesion element, such that the adhesion element adheres to the light-emitting body of the light-emitting element.

13. The display panel of claim 10, wherein the transfer substrate comprises a flat layer, a plurality of electric heating elements, a packaging layer, a plurality of expansion media, a plurality of flexible layers, and a plurality of adhesion elements, wherein
the plurality of electric heating elements are disposed on a surface of the flat layer;
the packaging layer covers the plurality of electric heating elements on the flat layer, and the packaging layer defines a plurality of accommodating holes penetrating through the packaging layer;
each of the plurality of accommodating holes is filled with the expansion medium, and the expansion medium is in contact with the electric heating element;
the flexible layer covers the plurality of expansion media, the plurality of adhesion elements are disposed on a surface of the flexible layer facing away from the plurality of expansion media, and a position of one expansion medium and a position of one adhesion element both correspond to a position of one adhesion region;
the electric heating element is configured to receive a current to generate heat; and
the expansion medium is configured to receive heat conducted by the electric heating element to expand to abut against the flexible layer, and the flexible layer abuts against the adhesion element, such that the adhesion element adheres to the light-emitting body of the light-emitting element.

14. The display panel of claim 13, wherein the transfer substrate further comprises a plurality of control transistors, wherein
each of the plurality of control transistors has a gate, an active device, a drain, and a source, and the active device is electrically connected with the drain and the source;
the drain of the control transistor is further electrically connected with one electric heating element;
the source of the control transistor is further electrically connected with a power-supply terminal; and
the gate of the control transistor is configured to receive a control signal to turn on the active device of the control transistor, to make the drain of the control transistor be electrically connected with the source of the control transistor, such that the electric heating element receives a current outputted by the power-supply terminal.

15. The display panel of claim 14, wherein the transfer substrate further comprises a second substrate, an insulating layer, and a passivation layer, wherein
the second substrate is disposed on one side of the flat layer facing away from the plurality of electric heating elements and is spaced apart from the flat layer;
gates of the plurality of control transistors are spaced apart from one another on one side of the second substrate facing the flat layer;
the insulating layer covers the gates of the plurality of control transistors on the second substrate;
active devices of the plurality of control transistors are disposed on a surface of the insulating layer facing away from the second substrate, a position of one active device corresponds to a position of one gate, the drain and the source are connected with the active device, and the drain is spaced apart from the source; and
the passivation layer covers the active devices, drains, and sources of the plurality of control transistors on the insulating layer, and the passivation layer is connected with the flat layer.

16. The display panel of claim 15, wherein
the flat layer defines a plurality of first vias penetrating through the flat layer, the passivation layer defines a plurality of second vias penetrating through the passivation layer, one drain is exposed from one second via, and one second via communicates with one first via; and
the transfer substrate further comprises a plurality of connecting electrodes, one connecting electrode is accommodated in one first via and one second via which are in communication, and one connecting electrode is connected with one electric heating element and one drain.

17. The display panel of claim 12, wherein the expansion medium is made of nitrogen, argon, water, or alcohol, and the flexible layer is made of polyester fiber or polyvinyl alcohol.

18. The display panel of claim 13, wherein wherein the expansion medium is made of nitrogen, argon, water, or alcohol, and the flexible layer is made of polyester fiber or polyvinyl alcohol.

19. A display device, comprising a housing and a display panel, wherein the display panel is received in the housing, a light-emitting side of the display panel is exposed from the housing, and the display panel comprises a driving substrate and a plurality of light-emitting elements disposed on one side of the driving substrate; wherein the plurality of light-emitting elements are transferred by a mass transfer assembly from a growth substrate to the driving substrate, each of the plurality of light-emitting elements comprises a light-emitting body initially connected with the growth substrate and two electrodes connected with the light-emitting body, and the mass transfer assembly comprises:
a temporary substrate, wherein the temporary substrate is configured to adhere two electrodes of each of a plurality of light-emitting elements on the growth substrate, to separate the plurality of light-emitting elements from the growth substrate, such that a light-emitting body of each of the plurality of light-emitting elements is suspended; and
a transfer substrate having a plurality of adhesion regions, wherein the transfer substrate is configured to adhere, through the adhesion regions, a light-emitting body of each of a plurality of light-emitting elements on the temporary substrate, to separate the plurality of light-emitting elements from the temporary substrate, such that two electrodes of each of the plurality of light-emitting elements are suspended; wherein one adhesion region adheres a light-emitting body of one light-emitting element; wherein positions of the plurality of adhesion regions on the transfer substrate are in one-to-one correspondence with positions of a plurality of binding regions on the driving substrate; wherein the transfer substrate is further configured to transfer a plurality of light-emitting elements on the transfer substrate to the side of the driving substrate, to bind two electrodes of each of the plurality of light-emitting elements to a corresponding binding region of the driving substrate.

20. The display device of claim 19, wherein the transfer substrate comprises a second substrate, a plurality of photothermal elements, a packaging layer, a plurality of expansion media, a flexible layer, and a plurality of adhesion elements, wherein
the plurality of photothermal elements are spaced apart from one another on a surface of the second substrate;
the packaging layer covers the plurality of photothermal elements on the second substrate, and the packaging layer defines a plurality of accommodating holes penetrating through the packaging layer;
each of the plurality of accommodating holes is filled with an expansion medium, and the expansion medium is in contact with the photothermal element;
the flexible layer shields and covers the plurality of expansion media, the plurality of adhesion elements are disposed on a surface of the flexible layer facing away from the plurality of expansion media, and a position of one expansion medium and a position of one adhesion element both correspond to a position of one adhesion region;
the photothermal element is configured to receive lights to generate heat; and
the expansion medium is configured to receive heat conducted by the photothermal element to expand to abut against the flexible layer, and the flexible layer abuts against the adhesion element, such that the adhesion element adheres to the light-emitting body of the light-emitting element.
